(19) United States
(12) Patent Application Publication
(10) Pub. No.: US 2009/0219030 A1
(43) Pub. Date: Sep. 3, 2009

(54) Methods and Systems for Detecting Rotor Field Ground Faults In Rotating Machinery

(75) Inventors: Sameh Ramadan Salem, Rexford, NY (US); Sheppard Salon, Schenectady, NY (US); Madabushi Venkatakrishnama Chari, Burnt Hills, NY (US); O-Mun Kwon, Troy, NY (US)

Correspondence Address: SUTHERLAND ASBILL & BRENNAN LLP, 999 PEACHTREE STREET, N.E., ATLANTA, GA, 30309, US

(73) Assignee: GENERAL ELECTRIC COMPANY, Schenectady, NY (US)

(21) Appl. No.: 12/040,448

(22) Filed: Feb. 29, 2008

(51) Int. Cl. G01R 31/34; G01R 31/08

(52) U.S. Cl. 324/510; 324/511

(57) ABSTRACT

Embodiments of the invention can include methods and systems for detecting rotor field ground faults in rotating machinery. In one embodiment, a system can include a rotor of the rotating machine comprising a plurality of field windings substantially disposed therein and a stator of the rotating machine comprising a plurality of stator windings substantially disposed therein, with an air gap existing between the rotor and the stator. The system can include a high-impedance grounding circuit at least temporarily connected between the rotor and a ground. Additionally, the system can include an air gap flux probe positioned at least temporarily between the rotor and the stator for measuring a magnetic flux density generated in the air gap during operation of the rotating machine. Finally, the system can further include an analyzer in electrical communication with the air gap flux probe for receiving an output of the air gap flux probe.

### TECHNICAL FIELD

The invention relates generally to rotating machinery, and more specifically relates to methods and systems for detecting rotor field ground faults in rotating machinery.

### BACKGROUND OF THE INVENTION

Rotating machinery, such as generators for converting mechanical energy to electrical energy, typically include a rotating component, the rotor, and a stationary component, the stator. The interaction of magnetic fields in the rotor and the stator is used to generate electric power.

The high alternating current (AC) output power is conventionally generated in the stator operating as an armature. The rotor includes multiple field windings, which in conventional generators is generally an arrangement of conductive wires or bars in the rotor. The field windings in the rotor are generally an annular array of conductive coil bars or cables (collectively referred to herein as coil bars) arranged in slots around the outer periphery of the rotor. The coil bars generally extend longitudinally along the length of the rotor and are connected by end turns at each end of the rotor. Insulation typically separates the coil bars and/or end turns of the rotor. An exciter circuit applies direct current (DC) to the coil bars of the rotor.

The insulation separating the coil bars and/or end turns occasionally may break down and cause short circuit between the coil bars or turns (also referred to herein as shorted turns). These shorted turns may exist at standstill or may be caused as a result of the centrifugal force of the rotor under load. Additionally, the coil components may cause the field windings to forge to the stator, causing a ground condition (also referred to herein as a ground fault). These ground faults may likewise exist at standstill, though are more typically caused by the centrifugal force of the rotor under load.

Shorted turns and ground faults change the power dissipation in the effected winding, which in turn may result in non-uniform heating of the rotor and thermally induced distortion and vibration. Therefore the risk of high-cost maintenance caused by shorted turns and ground faults encourages detecting each accurately and with specificity.

Current rotating machinery fault detection systems may use air gap flux probes to detect and locate shorted turns. Air gap flux probes sense the rate of change of radial and tangential flux as each slot in the field rotor passes by a search coil associated with the air gap flux probe. The search coil of the air gap flux probe is typically disposed in close proximity to the surface of the rotor, and the rotor passes the coil, flux leakages induce voltages in the coil. These voltages can be monitored to distinguish atypical flux characteristics. However, no systems yet leverage an air gap flux probe to similarly detect and locate ground faults in the rotor and to distinguish the located ground faults from shorted turns.

Thus, there is a need for systems and methods that can detect rotor field ground faults in rotating machinery.

There is a further need for systems and methods that can locate rotor field ground faults in rotating machinery.

### BRIEF DESCRIPTION OF THE INVENTION

Embodiments of the invention can address some or all of the needs described above.

In accordance with one exemplary embodiment of the invention, a system for detecting abnormalities in a rotating machine is provided for. The system can include a rotor of the rotating machine comprising a plurality of field windings substantially disposed therein. The system can further include a stator of the rotating machine comprising a plurality of stator windings substantially disposed therein. An air gap exists between the rotor and the stator. The system can include a high-impedance grounding circuit at least temporarily connected between the rotor and a ground. Additionally, the system can include an air gap flux probe positioned at least temporarily between the rotor and the stator for measuring a magnetic flux density generated in the air gap during operation of the rotating machine. Finally, the system can further include an analyzer in electrical communication with the air gap flux probe for receiving an output of the air gap flux probe.

In accordance with another exemplary embodiment of the invention, a method for detecting abnormalities in a rotating machine is provided. The method can include providing an air gap flux probe in an air gap existing between a rotor and a stator of the rotating machine and in close proximity to the rotor, operating the rotating machine at least at part load, and at least temporarily placing a high-impedance grounding circuit between the rotor and a ground, wherein the high-impedance grounding circuit can divert at least a portion of current to a ground fault that exists in at least one of a plurality of field windings disposed in the rotor. The method can further include measuring a magnetic flux density generated by the rotating machine with the air gap flux probe while the high-impedance grounding circuit is temporarily placed across the rotor, and analyzing the output of the air gap flux probe to detect an abnormality in the magnetic flux density measured.

In accordance with yet a further exemplary embodiment of the invention, a method for detecting abnormalities in a rotating machine is provided. The method can include receiving at least one measurement from an air gap flux probe positioned between a rotor comprising a plurality of field windings and a stator of the rotating machine, wherein the at least one measurement is associated with magnetic flux density existing between the rotor and the stator, and wherein the at least one measurement is taken while at least temporarily placing a high-impedance grounding circuit between the rotor and a ground. The method can further include analyzing the at least one measurement by comparing the at least one measurement to at least one baseline measurement, and determining that an abnormality exists in the magnetic flux density existing between the rotor and the stator.

Other embodiments and aspects of the invention will become apparent from the following description taken in conjunction with the following drawings.

### BRIEF DESCRIPTION OF THE DRAWINGS

FIG. 1 is an example diagram of rotating machinery as used with embodiments of the invention.

FIG. 2 is an example block diagram of a system used to implement various method embodiments of the invention.

FIG. 3 is an example block diagram illustrating a system according to an embodiment of the invention.

FIG. 4 is an example flowchart illustrating a method for detecting rotor field ground faults in rotating machinery according to an embodiment of the invention.

### DETAILED DESCRIPTION OF THE INVENTION

Embodiments of the invention now will be described more fully hereinafter with reference to the accompanying drawings, in which some, but not all embodiments are shown. Indeed, the invention may be embodied in many different forms and should not be construed as limited to the embodiments set forth herein; rather, these embodiments are provided so that this disclosure will satisfy applicable legal requirements. Like numbers refer to like elements throughout.

Methods and systems for detecting field ground faults in rotating machinery are provided for and described. Embodiments of such methods and systems provided can allow distinguishing ground faults from shorted turns in the rotor of the rotating machinery. At least some of embodiments of the methods and systems may include an air gap flux probe positioned in close proximity to the rotor and in between the rotor and stator of the rotating machinery. A high-impedance grounding circuit for applying a temporary ground across the rotor may also be included. The high-impedance component of the grounding circuit may allow current to flow to a ground fault in the rotor, if present, rather than the temporary ground created by the circuit means. Thus, by including a high-impedance ground temporarily across the rotor while obtaining measurements of the flux density, the air gap flux probe may detecting imbalances in the rotor caused by the ground fault (as well as imbalances caused by shorted turns) by their effects on the air gap flux density. Analyzing the outputs of the air gap flux probe with rotors under various shorted and ground faulted conditions may indicate that an imbalance caused by a ground fault at one or more locations of the rotor can be distinguished from an imbalance caused by shorted turns at the same or other locations of the rotor. Furthermore, the analysis of the outputs of the air gap flux probe may indicate that the locations, such as in which winding they occur, of both the ground fault and the shorted turns can be identified. The analysis performed may include comparing an output of the rotor in a balanced case, without any ground faults or shorted turns, to the output retrieved from the air gap flux probe when detecting field ground faults or shorted turns. The analysis may further include signal analysis and/or signal processing operations. For example, a signal processor may perform mathematical operations, such as a Fourier transform, or the like, to distinguish between air gap flux probe output signals. Accordingly, embodiments of the systems and methods described herein allow detection of field ground faults in rotating machinery. Furthermore, embodiments of the systems and methods described herein allow identifying the location of the ground faults in the rotor. Still further, embodiments of the systems and methods allow detecting and locating shorted field turns, and distinguishing the detected shorted field turns from the detected ground faults in the rotor.

Embodiments of the invention can perform or otherwise facilitate certain technical effects including, but not limited to, detecting abnormalities in a magnetic flux density in an air gap between a rotor and a stator of rotating machinery measured by an air gap flux probe while a high-impedance grounding circuit is applied between the rotor and a ground. Detecting the abnormalities in the magnetic flux density may have the technical effect of allowing for efficient and accurate identification and location of problematic ground faults to be corrected. Additionally, identifying and locating a ground fault in the rotor may have the further effect of allowing for efficient component repair or replacement, thus improving the efficient operation of the rotating machinery.

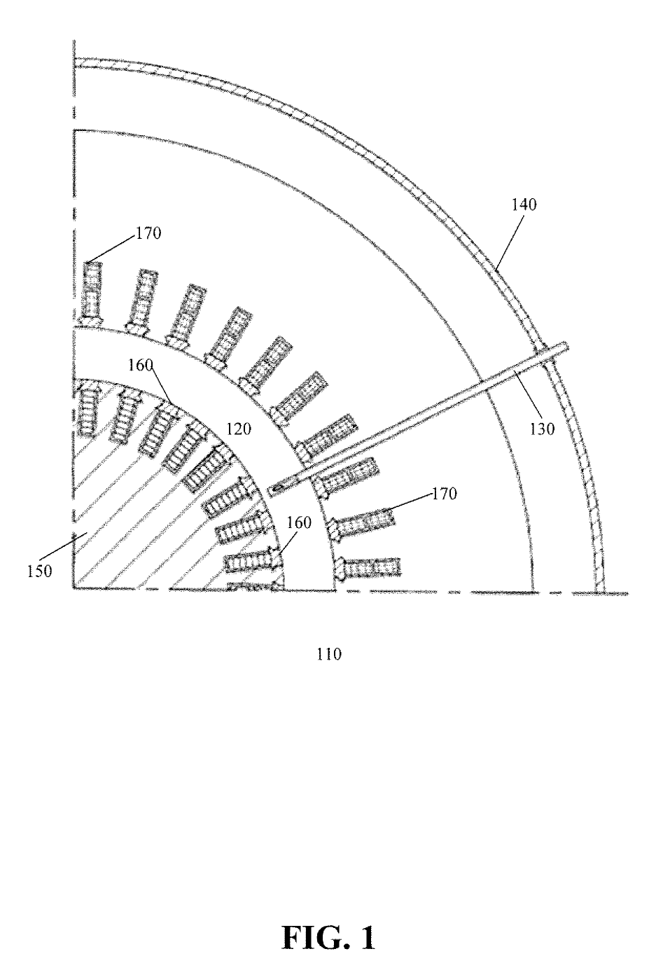

FIG. 1 illustrates a cross-sectional quarter view of an example rotating machinery 110. The rotating machinery 110 includes a rotor 150 and a stator 140. The rotor 150 may include multiple field windings 160 and the stator may include multiple stator windings 170. The rotor 150 and stator 140 interact, producing magnetic fields therebetween, thus providing electric power. The multiple field windings 160 may be excited by a direct current (DC) field supply, which is typically generated by an external DC generator and fed to the field windings 160, or in a brushless generator-rectifier assembly rotating within the rotor 150. The high alternating current (AC) output power is conventionally generated in the stator winding 170, which operates as an armature.

Each of the stator windings 170 may be configured as multiple mutually insulated conductor bars or conductive cables disposed in slots in the stator 140. End turns may be provided at the ends of the stator 140 to interconnect the ends of the conductor bars or cables of the stator windings 170. A rotor 150 may conventionally include two, four, or more poles formed by the arrangement of slots containing the field windings 160. The field windings 160 may also include end turns, like those of the stator windings 170. The field windings 160 may be symmetrically arranged in the slots on the rotor 150 with respect to the pole axis, and form an annular array around the rotor 150. An annular gap 120 exists between the field windings 160 of the rotor 150 and the stator windings 170 of the stator 140.

FIG. 1 illustrates an air gap flux probe 130 extending radially through the stator 140 and into the air gap 120. The air gap flux probe 130 may be permanently mounted in the stator 140 or it may be temporarily inserted into the air gap 120 between the stator 140 and the rotor 150. The air gap flux probe 130 may sense a field winding slot leakage flux, which may be indicative of rotor movement and, in particular, the alternating passage of field windings 160 and slots across the sensing field of the air gap flux probe 130. A typical air gap flux probe produces a voltage that is proportional to the rate of flux change as the rotor 150 turns. If either a shorted turn or a field ground fault is present at a location in any of the field windings 160, an aberration in the magnetic field flux density generated in the air gap may cause the air gap flux probe output to indicate as such. For example, the flux density may change slightly in magnitude but the harmonic content is different and distinctive, while the air gap flux probe 130 measures the voltage produced as the flux density wave travels by the air gap flux probe 110.

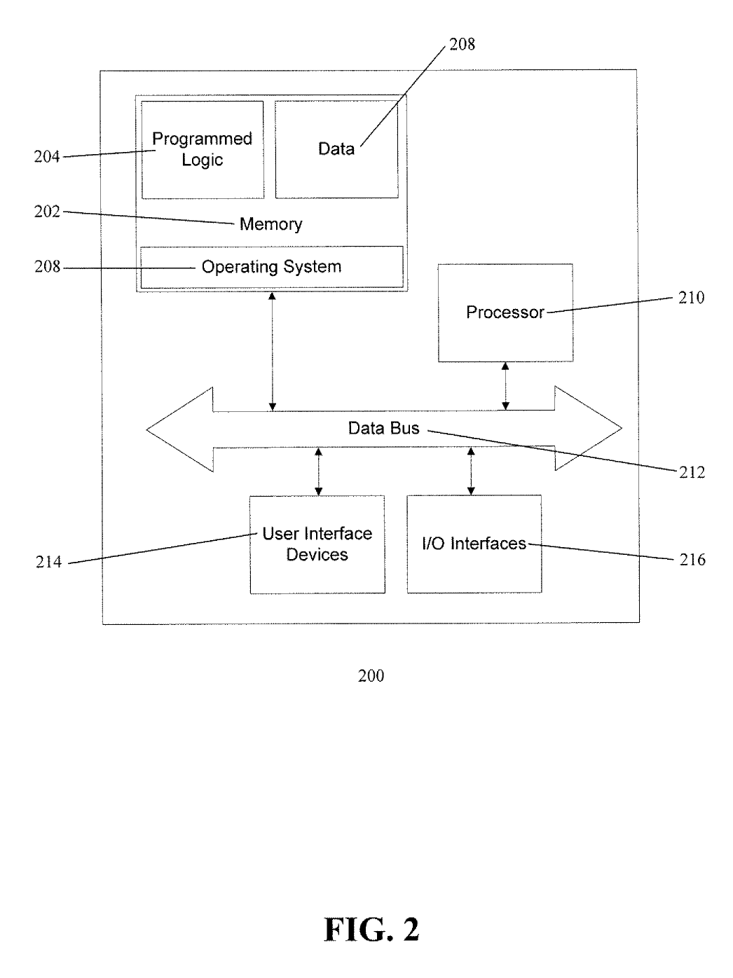

FIG. 2 illustrates, by way of a functional block diagram, an example analyzer 200, which may be used to implement at least certain elements of the method embodiments described. More specifically, the analyzer 200 may be in electrical communication with the air gap flux probe 130, and may carry out the monitoring, displaying, and analyzing of the air gap flux probe 130 outputs. The analyzer 200 may include a memory 202 that stores programmed logic 204, for example the software that performs at least some of the flux probe output analysis and signal processing, and may store data 206, such as air gap flux probe output, application code source files, configuration files, data dictionaries, assignment files, relay ladder logic files, extracted application code, generated application data, or the like. The memory 202 also may include an operating system 208. A processor 210 may utilize the operating system 208 to execute the programmed logic 204, and in doing so, also may utilize the data 206. A data bus 212 may provide communication between the memory 202 and the processor 210. Users may interface with the analyzer 200 via a user interface device(s) 214 such as a keyboard, mouse, control panel, or any other devices capable of communicating data to and from the analyzer 200. The analyzer 200 may also be in communication with other system components, such as a control system, sensor devices, or other systems on a network, via an I/O Interface 216.

In the illustrated embodiment, the analyzer 200 may be located remotely with respect to the rotating machinery or the machinery's control system; although it is appreciated that in some example embodiments, the analyzer 200 may be co-located or even integrated with the machinery or the control system. Further the analyzer 200 and the programmed logic 204 implemented thereby may include software, hardware, firmware, or any combination thereof. It should also be appreciated that multiple analyzers 200 may be used, whereby different features described herein may be executed on one or more different analyzers 200. However, for simplicity, the analyzer 200 will be referred to as a single component, though, it is appreciated that the analyzer 200 may be more than one computer station and/or more than one software application directed to different functions.

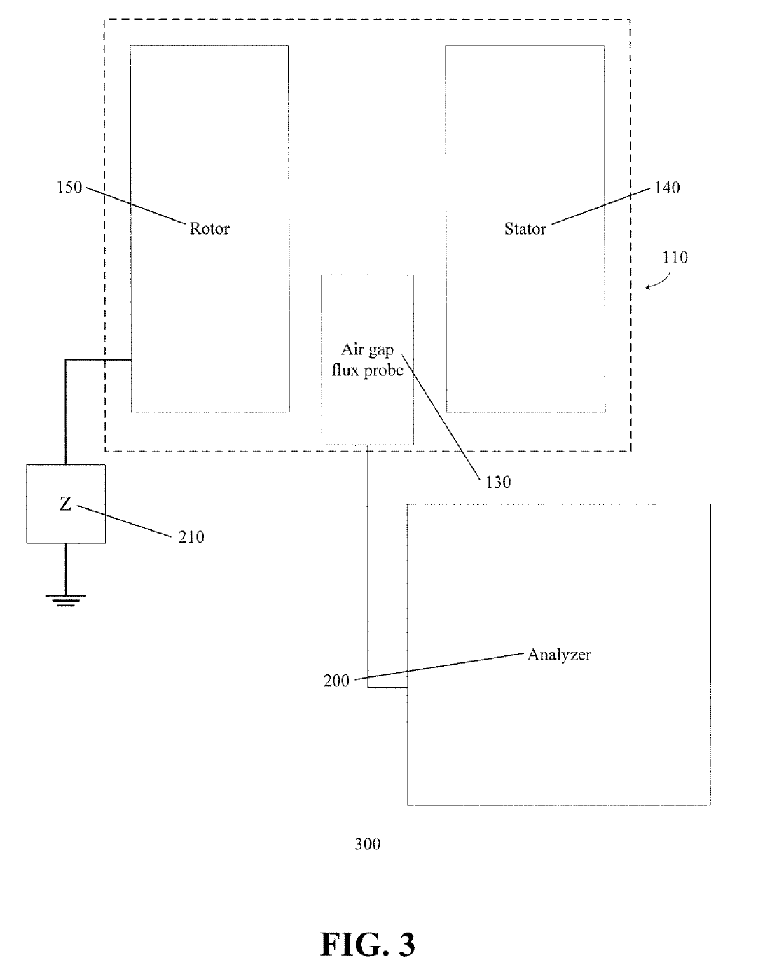

FIG. 3 illustrates a functional block diagram 300 of an example embodiment of the system for detecting and locating field ground faults and distinguishing them from shorted field turns, as described herein. As described above, the rotating machinery 110 includes a rotor 150 and a stator 140. The rotating machinery components, for example, the rotor 150 and the stator 140, are represented in a general manner for illustrative purposes only, as it is appreciated that the rotor includes field windings and slots and the stator includes stator windings and slots, as is described with reference to FIG. 1. An air gap flux probe 130 is positioned in the air gap between the rotor 150 and the stator 140. The air gap flux probe 130 may be, for example, a search coil or a Hall probe, each for measuring flux density versus time. The air gap flux probe 130 may be temporarily attached to the rotating machinery or it may be permanently installed.

The air gap flux probe 130 is in electrical communication with the analyzer 200, as is more fully described above with reference to FIG. 2. The analyzer 200 may perform at least some of the elements of the methods for detecting field ground faults in the rotor 150. For example, the analyzer 200 may include an output monitor that displays, for example, in tablature or graphical form, the output of the air gap flux probe 130. The output display may be real time, or the output may be stored in a memory of the analyzer 200 and reviewed and/or displayed after measured. For example, the memory of the analyzer 200 may store the output from the air gap flux probe 130 to compile data for batch analysis. Furthermore, the analyzer 200 includes a processor and programming logic that may store one or more routines for performing signal processing analyses on the output of the air gap flux probe 130. For example, the analyzer may perform mathematical operations on the output of the air gap flux probe 130, such as performing a Fourier transform, a wavelet analysis, a Laplace transform, a neural network analysis, or the like, for further analysis of the output and comparison to baseline calculations.

The system may also include a high-impedance grounding circuit 210 removably applied between the rotor 150 and ground, so as to divert current through the rotor and to the grounded location in the field turns. The high-impedance grounding circuit 210 may be temporarily applied between the rotor 150 and ground when attempting to detect any field rotor ground faults, and removed when not detecting. The grounding circuit 210 may be removably applied to the rotor by a switch, or the like.

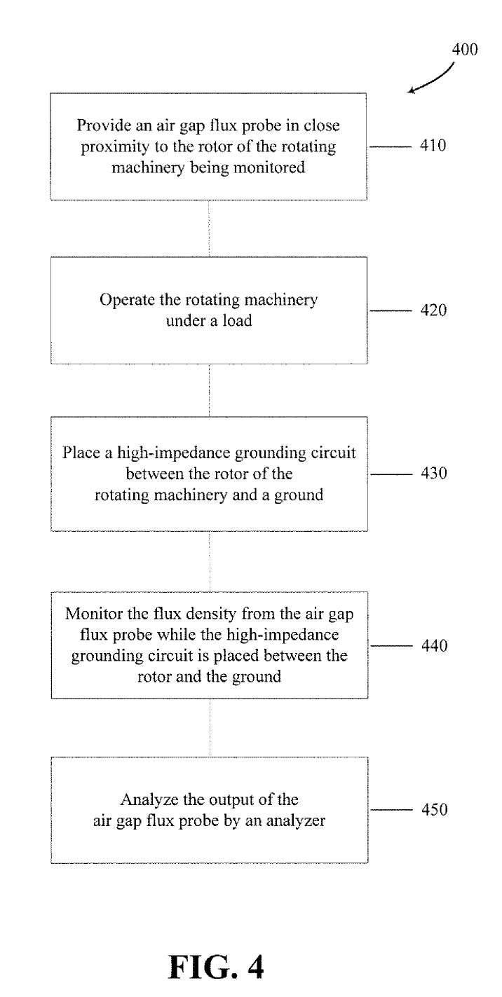

FIG. 4 illustrates an example method by which an embodiment of the invention may operate. Provided is a flowchart 400 illustrating the detection of a field ground fault in a rotor of rotating machinery, an embodiment of which is more fully described in reference to FIGS. 1 and 3.

At block 410, an air gap flux probe is provided for, placed in close proximity to the rotor of the rotating machinery. The air gap flux probe may be, for example, a search coil or a Hall probe that measures over time the flux density in the air gap between the rotor and the stator of the rotating machinery.

Block 410 is followed by block 420, in which the rotating machinery may operate at least at partial load. However, it is appreciated that these same methods and systems as described herein may be used to detect field ground faults and/or shorted field turns additionally when the rotating machinery is not under a load.

Block 420 is followed by block 430, in which a high-impedance grounding circuit is applied across the rotor to detect a field ground fault. The high-impedance grounding circuit allows the rotor to be ground for the period of time when the measurements by the air gap flux probe are made. Furthermore, the grounding circuit includes a high-impedance ground because rotors are generally ungrounded, and if there exists a rotor ground, current would not flow. Therefore, by including a high-impedance grounding circuit, current will be diverted to the ground or grounds having a lower impedance.

Block 440 follows block 430, in which the air gap flux probe in combination with the analyzer, both described in more detail above with reference to FIG. 3, measure the air gap flux density as output from the flux probe. This is performed while the high-impedance grounding circuit is applied across the rotor, as at block 430. The output of the air gap flux probe will generally be the air gap flux density over the time during which the measurements are taken. Because of the nature of the rotating machinery and the configuration of the field windings in the rotor and the stator windings in the stator, as is more fully described with reference to FIG. 1, there is a correlation between the time and the location of the specific field turn (or coil) on the rotor. More specifically, the flux density changes (in an oscillatory manner) as a result of the alternating passage of a winding and then a slot. Thus, plotting the flux density output over time indicates the varying flux density at each winding, with the earliest variation represented on the plot being the beginning winding and the latest variation (in one cycle) being the ending winding.

Finally, block 450, which follows block 440, illustrates that the output from the air gap flux probe may be analyzed by the analyzer. The analysis performed on the air gap flux probe output may include a visual comparison of the waveforms generated by the flux probe by a user, or may include signal processing to detect variations in the output so as to identify field ground faults, shorted field turns, and their respective locations on the field windings. In one example embodiment the waveform output from the air gap flux probe during measurement is compared to a baseline measurement that was made on the rotor having no shorted field turns or field ground faults. The comparison may be a visual one by overlaying the two waveforms to identify dissimilarities, by plotting flux density lines as they relates to a model of the rotating machinery (such as a flux density line plot), or by shading the variations in flux density as it relates to a model of the rotating machinery (such as a flux density color shade plot). Alternatively, the comparison may be accomplished by processing performed by the analyzer, such as through filtering, using the baseline measurement as at least partial input to the filter. In another example embodiment, the waveform output from the air gap flux probe during measurement may be subjected to signal processing analysis by the analyzer. For example, a Fourier transform, a wavelet analysis, a Laplace transform, a neural network analysis, or the like, may be performed to compare the output and to baseline calculations. The location of the ground fault may be identified by comparing the variation in flux density to the baseline, and the location along the time axis of the waveform output or the location as it relates to a model of the rotating machinery.

References are made to block diagrams of systems, methods, apparatuses, and computer program products according to example embodiments of the invention. It will be understood that at least some of the blocks of the block diagrams, and combinations of blocks in the block diagrams, respectively, may be implemented at least partially by computer program instructions. These computer program instructions may be loaded onto a general purpose computer, special purpose computer, special purpose hardware-based computer, or other programmable data processing apparatus to produce a machine, such that the instructions which execute on the computer or other programmable data processing apparatus create means for implementing the functionality of at least some of the blocks of the block diagrams, or combinations of blocks in the block diagrams discussed.

These computer program instructions may also be stored in a computer-readable memory that can direct a computer or other programmable data processing apparatus to function in a particular manner, such that the instructions stored in the computer-readable memory produce an article of manufacture including instruction means that implement the function specified in the block or blocks. The computer program instructions may also be loaded onto a computer or other programmable data processing apparatus to cause a series of operational elements to be performed on the computer or other programmable apparatus to produce a computer implemented process such that the instructions that execute on the computer or other programmable apparatus provide elements for implementing the functions specified in the block or blocks.

One or more components of the systems and one or more elements of the methods described herein may be implemented through an application program running on an operating system of a computer. They also may be practiced with other computer system configurations, including hand-held devices, multiprocessor systems, microprocessor based, or programmable consumer electronics, mini-computers, mainframe computers, etc.

Application programs that are components of the systems and methods described herein may include routines, programs, components, data structures, etc. that implement certain abstract data types and perform certain tasks or actions. In a distributed computing environment, the application program (in whole or in part) may be located in local memory, or in other storage. In addition, or in the alternative, the application program (in whole or in part) may be located in remote memory or in storage to allow for circumstances where tasks are performed by remote processing devices linked through a communications network.

Many modifications and other embodiments of the invention set forth herein to which these descriptions pertain will come to mind having the benefit of the teachings presented in the foregoing descriptions and the associated drawings. Thus, it will be appreciated that the invention may be embodied in many forms and should not be limited to the example embodiments described above. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A system for detecting abnormalities in a rotating machine, comprising:
a rotor of the rotating machine comprising a plurality of field windings substantially disposed therein;
a stator of the rotating machine comprising a plurality of stator windings substantially disposed therein;
an air gap existing between the rotor and the stator;
a high-impedance grounding circuit at least temporarily connected between the rotor and a ground;
an air gap flux probe positioned at least temporarily between the rotor and the stator for measuring a magnetic flux density generated in the air gap during operation of the rotating machine; and
an analyzer in electrical communication with the air gap flux probe for receiving an output of the air gap flux probe.

2. The system of claim 1, wherein the rotating machine comprises a turbogenerator.

3. The system of claim 1, wherein the air gap flux probe and the analyzer are operable to detect an abnormality in the magnetic flux density measured.

4. The system of claim 3, wherein the abnormality indicates at least one of (a) a shorted field winding or (b) a ground fault in the rotor.

5. The system of claim 4, wherein the air gap flux probe and the analyzer are operable to locate at least one of the shorted field winding or the ground fault as occurring at a specific field winding in the plurality of field windings.

6. The system of claim 1, wherein the analyzer is operable to display at least one of (a) a waveform plotting the measured magnetic flux density over time, (b) a magnetic flux density line plot spatially related to a graphic model of the rotating machine, or (c) a magnetic flux density color shade plot spatially related to a graphic model of the rotating machine.

7. The system of claim 1, wherein the analyzer is operable to compare the measured magnetic flux density generated by the rotating machine during operation to a baseline magnetic flux density measurement generated by the rotating machine without ground faults and without shorts existing in any of the plurality of field windings.

8. A method for detecting abnormalities in a rotating machine, comprising:
providing an air gap flux probe in an air gap existing between a rotor and a stator of the rotating machine and in close proximity to the rotor;
operating the rotating machine at least at part load;
at least temporarily placing a high-impedance grounding circuit between the rotor and a ground, wherein the high-impedance grounding circuit can divert at least a portion of current to a ground fault that exists in at least one of a plurality of field windings disposed in the rotor;
measuring a magnetic flux density generated by the rotating machine with the air gap flux probe while the high-impedance grounding circuit is temporarily placed across the rotor; and
analyzing the output of the air gap flux probe to detect an abnormality in the magnetic flux density measured.

9. The method of claim 8, wherein the rotating machinery comprises a turbogenerator.

10. The method of claim 8, further comprising determining as the cause of the abnormality detected at least one of (a) a shorted field winding or (b) a ground fault in the rotor.

11. The method of claim 10, further comprising locating the shorted field winding or the ground fault as occurring at least one field winding in the plurality of field windings.

12. The method of claim 8, further comprising:
determining that at least one shorted field winding and at least one ground fault in the rotor are the cause of the abnormality detected; and
distinguishing the at least one ground fault from the at least one shorted field winding.

13. The method of claim 12, further comprising:
locating the at least one shorted field winding as occurring at least one field winding in the plurality of field windings; and
locating the at least one ground fault as occurring at least one field winding in the plurality of field windings.

14. The method of claim 8, wherein analyzing the output of the air gap flux probe comprises at least one of (a) generating and analyzing a waveform plotting the measured magnetic flux density over time, (b) generating and analyzing a magnetic flux density line plot spatially related to a graphic model of the rotating machine, or (c) generating and analyzing a magnetic flux density color shade plot spatially related to a graphic model of the rotating machine.

15. The method of claim 8, wherein analyzing the output of the air gap flux probe comprises comparing the measured magnetic flux density generated by the rotating machine during operation to a baseline magnetic flux density measurement generated by the rotating machine without ground faults or without shorts existing in any of the plurality of field windings.

16. A method for detecting abnormalities in a rotating machine, comprising:
receiving at least one measurement from an air gap flux probe positioned between a rotor comprising a plurality of field windings and a stator of the rotating machine, wherein the at least one measurement is associated with magnetic flux density existing between the rotor and the stator, and wherein the at least one measurement is taken while at least temporarily placing a high-impedance grounding circuit between the rotor and a ground;
analyzing the at least one measurement by comparing the at least one measurement to at least one baseline measurement; and
determining that an abnormality exists in the magnetic flux density existing between the rotor and the stator.

17. The method of claim 16, further comprising determining as the cause of the abnormality detected at least one of (a) a shorted field winding or (b) a ground fault in the rotor.

18. The method of claim 17, further comprising determining that the shorted field winding or the ground fault occurs at least one field winding in the plurality of field windings.

19. The method of claim 16, further comprising:
determining that at least one shorted field winding and at least one ground fault in the rotor are the cause of the abnormality detected; and
distinguishing the at least one ground fault from the at least one shorted field winding.

20. The method of claim 19, further comprising:
determining that the at least one shorted field winding occurs at least one field winding in the plurality of field windings; and
determining that the at least one ground fault occurs at least one field winding in the plurality of field windings.
